(19) United States
(12) Patent Application Publication
(10) Pub. No.: US 2020/0146194 A1
(43) Pub. Date: May 7, 2020

(54) BACK-DRILLED VIA PROBING TECHNIQUES

(71) Applicant: International Business Machines Corporation, Armonk, NY (US)

(72) Inventors: LAYNE A. BERGE, ROCHESTER, MN (US); JASON J. BJORGAARD, ROCHESTER, MN (US); MATTHEW S. DOYLE, CHATFIELD, MN (US); THOMAS W. LIANG, ROCHESTER, MN (US); JOHN R. DANGLER, ROCHESTER, MN (US); MANUEL OROZCO, ROCHESTER, MN (US)

(21) Appl. No.: 16/181,703

(22) Filed: Nov. 6, 2018

(51) Int. Cl. H05K 13/08; H05K 13/00; H05K 3/40; H05K 3/34; G01R 31/28

(52) U.S. Cl. CPC H05K 13/082; H05K 13/0015; H05K 3/4038; H05K 2203/0195; G01R 31/2818; H05K 2203/166; H05K 2203/162; H05K 3/3494

(57) ABSTRACT

Various back-drilled via probing techniques are described. In some cases, a screw may be utilized to establish a conductive pathway through a voided portion of a back-drilled via to a plated portion of the back-drilled via to enable back-drilled via probing. In other cases, a combination of solder paste and a wire may be utilized to establish the conductive pathway to enable back-drilled via probing. In other cases, a compliant pin that includes a metallized particle interconnect material may be utilized to establish the conductive pathway to enable back-drilled via probing. In other cases, a combination of an ultraviolet curable film and a light pipe may be utilized to establish a conductive pathway the conductive pathway to enable back-drilled via probing.

### BACKGROUND

For high-speed serial links, a common practice is to back-drill vias, eliminating a “stub” which hinders the successful transfer of data on an interface. For debugging purposes, it is difficult to solder probes onto an interface which has been back-drilled.

### SUMMARY

According to an embodiment, a process of back-drilled via probing includes aligning a screw for insertion into a voided portion of a back-drilled via of a printed circuit board. The process includes rotating the screw to establish a conductive pathway through the voided portion of the back-drilled via to a plated portion of the back-drilled via. The process further includes coupling a probe to the screw using a probe lead for back-drilled via probing.

According to another embodiment, a process of back-drilled via probing includes dispensing solder paste into a voided portion of a back-drilled via of a printed circuit board. The process includes inserting a wire (or multiple wires) into the solder paste, applying a current to the wire to reflow the solder paste, and allowing the solder paste to cure to establish a conductive pathway through the voided portion of the back-drilled via to a plated portion of the back-drilled via. The process includes coupling a probe to the wire using a probe lead for back-drilled via probing.

According to yet another embodiment, a process of back-drilled via probing includes injecting ultraviolet (UV) curable film into a voided portion of a back-drilled via of a printed circuit board. The process also includes inserting a light pipe having a conductive outer sheath into the UV curable film and curing the UV curable film by applying UV light within the light pipe to establish a conductive pathway through the voided portion of the back-drilled via to a plated portion of the back-drilled via. The process further includes coupling a probe to the conductive outer sheath of the light pipe using a probe lead for back-drilled via probing.

The foregoing and other objects, features, and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIGS. 1A to 1C illustrate a first embodiment of a back-drilled via probing technique.

FIGS. 2A to 2F illustrate a second embodiment of a back-drilled via probing technique.

FIG. 3 illustrates a third embodiment of a back-drilled via probing technique.

FIGS. 4A to 4D illustrate a fourth embodiment of a back-drilled via probing technique.

### DETAILED DESCRIPTION

The present disclosure describes back-drilled via probing techniques. In one embodiment of the present disclosure, a small screw may be inserted into a voided portion of a back-drilled via to enable probing. In another embodiment of the present disclosure, solder paste and a nickel-chromium (nichrome) wire may be used to solder a probe in the middle of the board (z-axis). In yet another embodiment, a compliant pin with metallized particle interconnect (MPI) material may be used to establish a conductive pathway for probing. In another embodiment, a light pipe with a UV-curable film may be utilized to establish the conductive pathway.

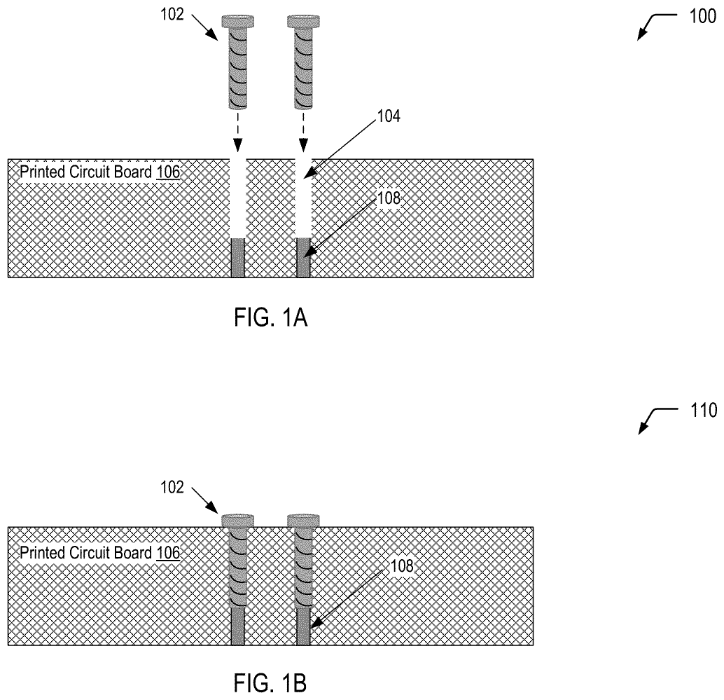

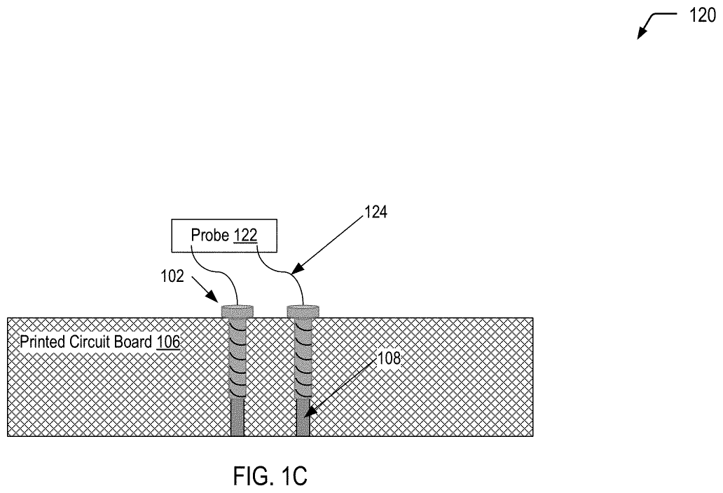

FIGS. 1A to 1C depict a first embodiment of a back-drilled via probing technique. FIG. 1A illustrates a first perspective view 100 of a first stage of the back-drilled via probing technique in which a screw 102 is aligned for insertion into a voided portion 104 of a back-drilled via of a printed circuit board 106. FIG. 1A illustrates an embodiment in which the printed circuit board 106 includes multiple back-drilled vias (e.g., associated with a high-speed interface of a differential pair), with individual screws being utilized for each back-drilled via. FIG. 1B illustrates a second perspective view 110 of a second stage of the back-drilled via probing technique in which the screw 102 is rotated to form a conductive pathway through the voided portion 104 to a plated portion 108 of the back-drilled via.

FIG. 1C illustrates a third perspective view 120 of a third stage of the back-drilled via probing technique where a probe 122 is coupled to the screw 102 using a probe lead 124. In some cases, the probe 122 may be coupled to the screw 102 by soldering the probe lead 124 to a screw head of the screw 102. In other cases, the probe 122 may be coupled to the screw 102 by mechanically fixing the probe lead 124 to the screw 102, such as by clipping the probe lead 124 to the screw head using an actuatable element (an “alligator” clip) or by wrapping the probe lead 124 around the screw 102.

Thus, FIGS. 1A to 1C illustrate an example of a process that utilizes a screw to establish a conductive pathway through a voided portion of a back-drilled via to a plated portion of the back-drilled via to enable back-drilled via probing.

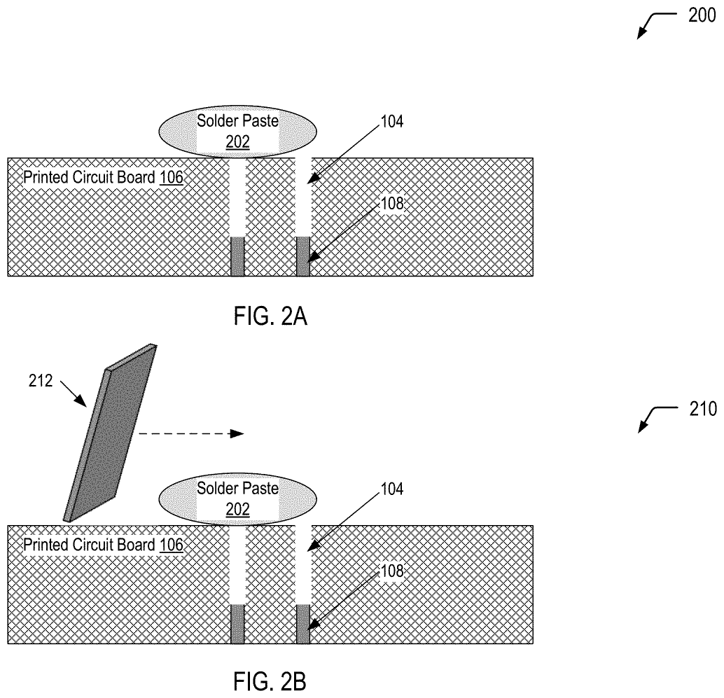

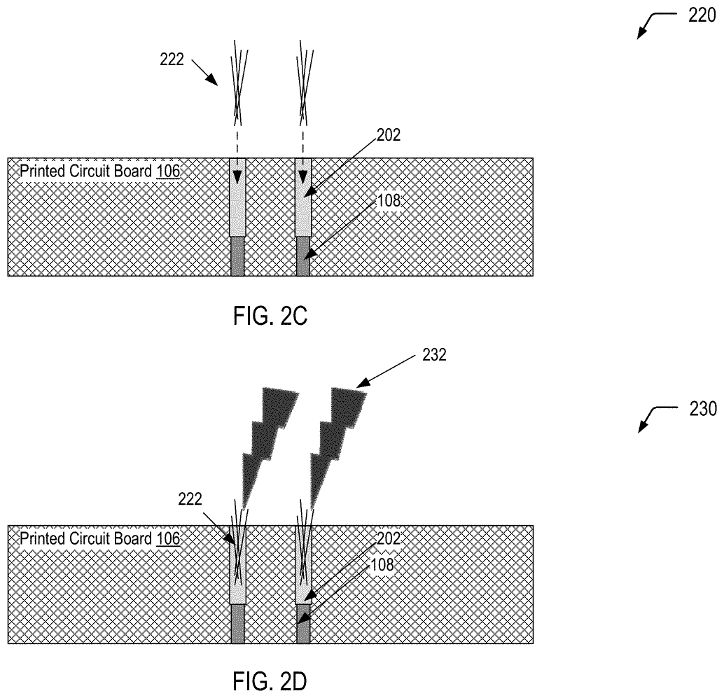

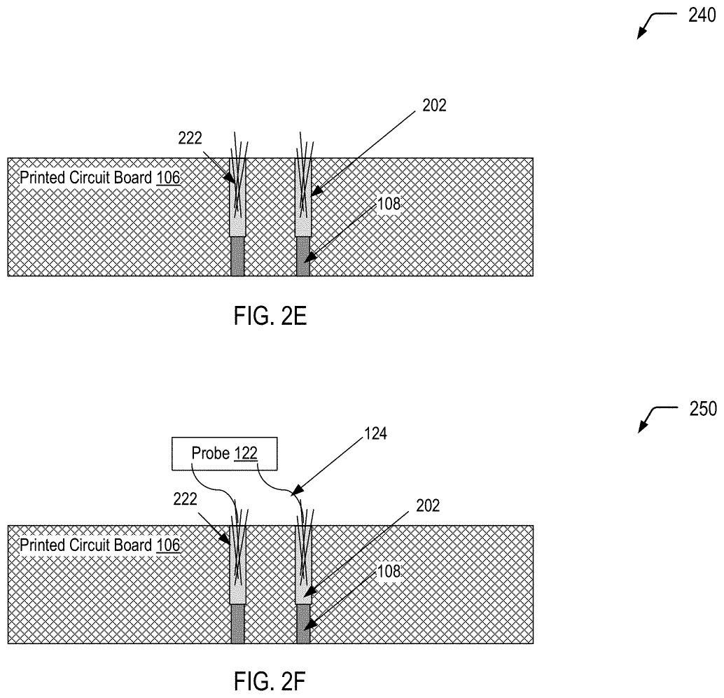

FIGS. 2A to 2F depict a second embodiment of a back-drilled via probing technique. FIG. 2A illustrates a first perspective view 200 of a first stage of the back-drilled via probing technique in which solder paste 202 is applied to the backside of the PCB 106 over the voided portion 104 of the back-drilled vias. FIG. 2B illustrates a first perspective view 210 of a second stage of the back-drilled via probing technique in which an edged surface 212 (e.g., a squeegee) is used to sweep the solder paste 202 into the voided portion 104. In alternative embodiments, the solder paste 202 may be injected into the voided portion 104.

FIG. 2C illustrates a first perspective view 220 of a third stage of the back-drilled via probing technique in which a wire 222 (or multiple wires) is inserted into the solder paste 202. FIG. 2D illustrates a fourth perspective view 230 of a fourth stage of the back-drilled via probing technique in which current 232 is run through the wire 222 to heat the solder paste 202 to a melting point to reflow the solder paste 202.

FIG. 2E illustrates a fifth perspective view 240 of a fifth stage of the back-drilled via probing technique where the solder paste 202 is allowed to cure, fusing the solder paste 202 and the wire 222 together. FIG. 2F illustrates a sixth perspective view 250 of a sixth stage of the back-drilled via probing technique where the probe 122 is connected to the wire 222 using the probe leads 124. In some cases, the probe 122 may be coupled to the wire 222 by soldering the probe lead 124 to the wire 222. In other cases, the probe 122 may be coupled to the wire 222 by mechanically fixing the probe lead 124 to the wire 222, such as by clipping the probe lead 124 to the wire 222 using an actuatable element.

Thus, FIGS. 2A to 2F illustrate an example of a process that utilizes a combination of solder paste and one or more wires to establish a conductive pathway through a voided portion of a back-drilled via to a plated portion of the back-drilled via to enable back-drilled via probing.

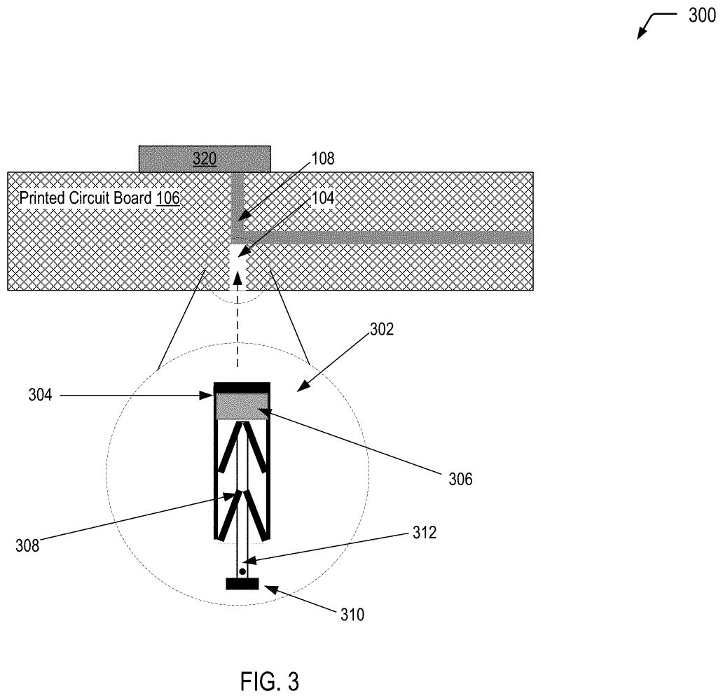

FIG. 3 is a perspective view 300 of a third embodiment of a back-drilled via probing technique that utilizes a compliant pin connector 302. The compliant pin connector 302 may be inserted into the voided portion 104 of a back-drilled via, such that a connector touches a bottom of the conductive material 108. The compliant pin connector 302 includes metallized particle interconnect (MPI) material 306 to provide an ohmic connection to the conductive material 108. The compliant pin connector 302 includes winglets 308 that may be expanded using a screw applicator 310 for improved mechanical stability within the voided portion 104 via back-drilled via. Further, the winglets 308 enable removal of the compliant pin connector 302 by collapsing the winglets 308 using the screw applicator 310. In the embodiment depicted in FIG. 3, the compliant pin connector 302 includes a slot 312 for insertion of the probe tips 124 and connection to the probe 122.

Thus, FIG. 3 illustrates an example of a process that utilizes a modified compliant pin that includes MPI material to establish a conductive pathway through a voided portion of a back-drilled via to a plated portion of the back-drilled via to enable back-drilled via probing.

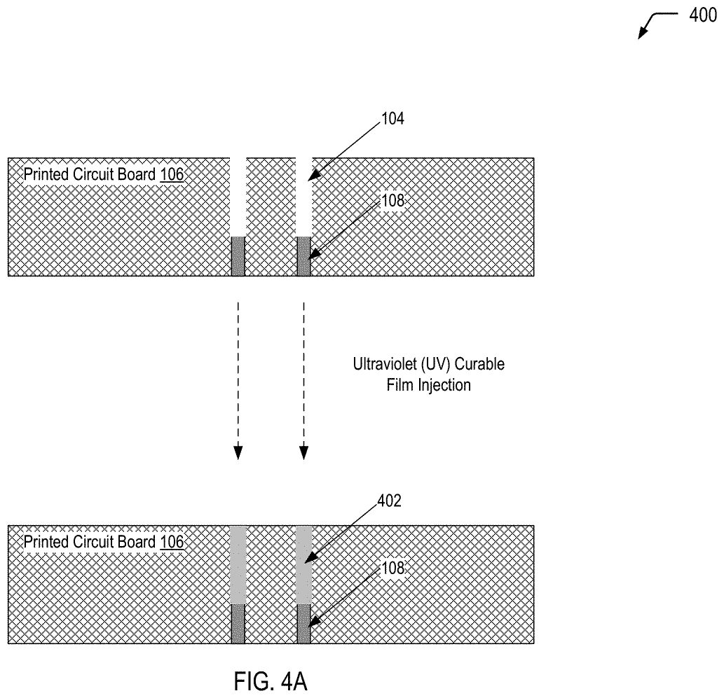

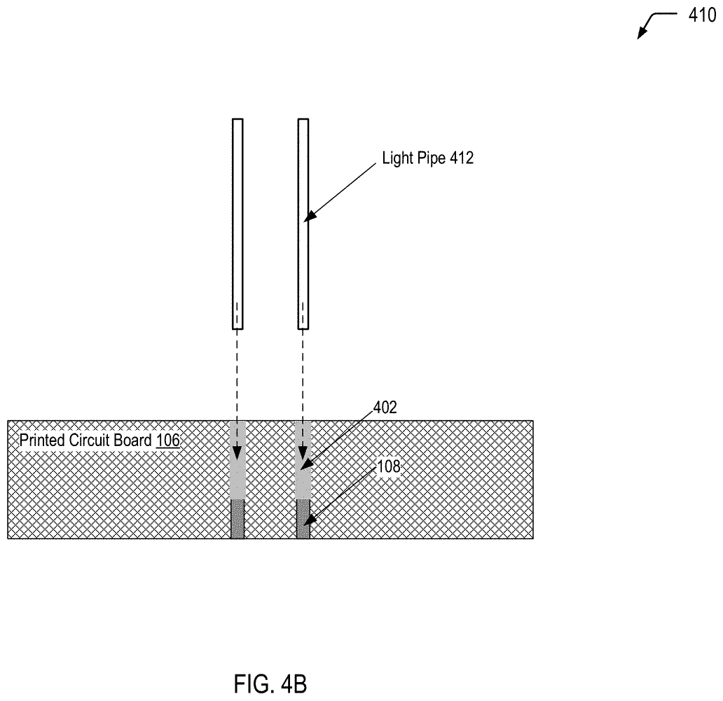

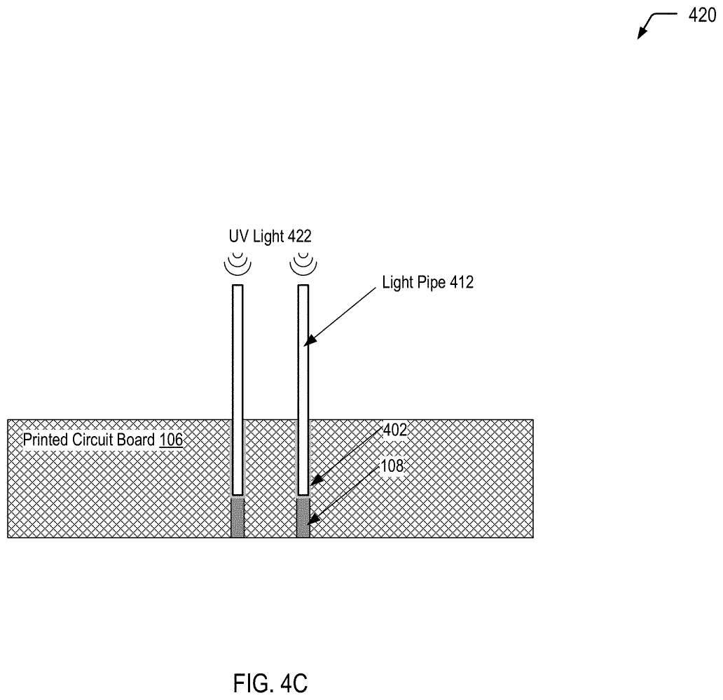

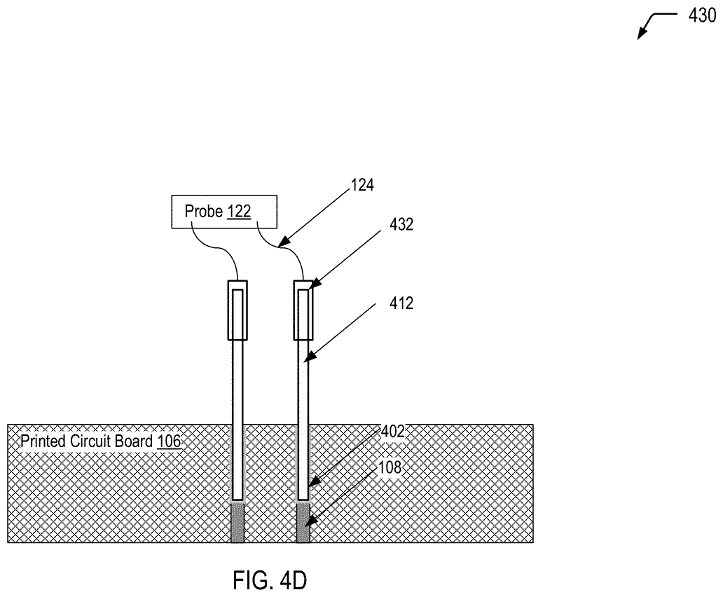

FIGS. 4A to 4D depict a fourth embodiment of a back-drilled via probing technique. FIG. 4A illustrates a first perspective view 400 of a first stage of the back-drilled via probing technique in which a UV curable film 402 is injected into the voided portion 104 of the back-drilled vias. FIG. 4B illustrates a second perspective view 410 of a second stage of the back-drilled via probing technique in which a light pipe 412 having a conductive outer sheath is inserted into the UV curable film 402. FIG. 4C illustrates a third perspective view 420 of a third stage of the back-drilled via probing technique in which UV light 422 is applied to cure the UV curable film 402. The UV curing electrically connects the conductive outer sheath of the light pipe 412 to the via stub.

FIG. 4D is a fourth perspective view 430 of a fourth stage of the back-drilled via probing technique in which the probe 122 is attached to the conductive outer sheath of the light pipe 412. In the embodiment depicted in FIG. 4D, a slip-on conductive probe sleeve 432 is utilized to couple the probe lead 124 to the conductive outer sheath of the light pipe 412. For example, the probe 122 may be coupled to the light pipe 412 by soldering the probe lead 124 to the slip-on conductive probe sleeve or by mechanically fixing the probe lead 124 to the slip-on conductive probe sleeve using an actuatable element. In alternative embodiments, the probe lead 124 may be directly coupled to the conductive outer sheath of the light pipe 412.

Thus, FIGS. 4A to 4D illustrate an example of a process that utilizes a combination of a UV curable film and a light pipe to establish a conductive pathway through a voided portion of a back-drilled via to a plated portion of the back-drilled via to enable back-drilled via probing.

It will be understood from the foregoing description that modifications and changes may be made in various embodiments of the present invention. The descriptions in this specification are for purposes of illustration only and are not to be construed in a limiting sense. The scope of the present invention is limited only by the language of the following claims.

What is claimed is:

1. A process of back-drilled via probing, the process comprising:
aligning a screw for insertion into a voided portion of a back-drilled via of a printed circuit board;
rotating the screw to establish a conductive pathway through the voided portion of the back-drilled via to a plated portion of the back-drilled via; and
coupling a probe to the screw using a probe lead for back-drilled via probing.

2. The process of claim 1, wherein coupling the probe to the screw using the probe lead includes soldering the probe lead to a screw head of the screw.

3. The process of claim 1, wherein coupling the probe to the screw using the probe lead includes mechanically fixing the probe lead to the screw.

4. The process of claim 3, wherein the probe lead includes an actuatable element for mechanically fixing the probe lead to a screw head of the screw.

5. The process of claim 1, wherein the back-drilled via is associated with a high-speed interface of a differential pair.

6. A process of back-drilled via probing, the process comprising:
dispensing solder paste into a voided portion of a back-drilled via of a printed circuit board;
inserting a wire into the solder paste;
applying a current to the wire to reflow the solder paste;
allowing the solder paste to cure to establish a conductive pathway through the voided portion of the back-drilled via to a plated portion of the back-drilled via; and
coupling a probe to the wire using a probe lead for back-drilled via probing.

7. The process of claim 6, wherein the wire is formed from a nickel-chromium alloy.

8. The process of claim 6, wherein dispensing the solder paste includes applying the solder paste over the voided portion and utilizing an edged surface to sweep the solder paste into the voided portion.

9. The process of claim 6, wherein dispensing the solder paste includes injecting the solder paste into the voided portion.

10. The process of claim 6, wherein coupling the probe to the wire using the probe lead includes soldering the probe lead to the wire.

11. The process of claim 6, wherein coupling the probe to the wire using the probe lead includes mechanically fixing the probe lead to the wire.

12. The process of claim 11, wherein the probe lead includes an actuatable element for mechanically fixing the probe lead to the wire.

13. The process of claim 6, wherein the back-drilled via is associated with a high-speed interface of a differential pair.

14. A process of back-drilled via probing, the process comprising:
injecting ultraviolet (UV) curable film into a voided portion of a back-drilled via of a printed circuit board;
inserting a light pipe having a conductive outer sheath into the UV curable film;
curing the UV curable film by applying UV light within the light pipe to establish a conductive pathway through the voided portion of the back-drilled via to a plated portion of the back-drilled via; and
utilizing a probe lead to couple a probe to the conductive outer sheath of the light pipe for back-drilled via probing.

15. The process of claim 14, wherein a slip-on conductive probe sleeve is utilized to couple the probe lead to the conductive outer sheath of the light pipe.

16. The process of claim 15, wherein the probe lead is coupled to the conductive outer sheath of the light pipe by soldering the probe lead to the slip-on conductive probe sleeve.

17. The process of claim 15, wherein the probe lead is coupled to the conductive outer sheath of the light pipe by mechanically fixing the probe lead to the slip-on conductive probe sleeve.

18. The process of claim 17, wherein the probe lead includes an actuatable element for mechanically fixing the probe lead to the slip-on conductive probe sleeve.

19. The process of claim 14, wherein the probe lead is directly coupled to the conductive outer sheath of the light pipe.

20. The process of claim 14, wherein the back-drilled via is associated with a high-speed interface of a differential pair.
